(19) United States
(12) Patent Application Publication
(10) Pub. No.: US 2026/0293609 A1
(43) Pub. Date: Sep. 24, 2026

(54) IN-SITU BEVEL CLEANING IN PECVD CHAMBER

(71) Applicant: Applied Materials, Inc., Santa Clara, CA (US)

(72) Inventors: Deepesh RAI, San Jose, CA (US); Ara JUNG, Santa Clara, CA (US); Victor ZAMARIAN, Cupertino, CA (US); Zhijun JIANG, Sunnyvale, CA (US); Lu LIU, San Jose, CA (US); Karthik JANAKIRAMAN, San Jose, CA (US); Wen FU, Sunnyvale, CA (US)

(21) Appl. No.: 19/088,665

(22) Filed: Mar. 24, 2025

(51) Int. Cl. H01L 21/687; H01J 37/32; H01L 21/683

(52) U.S. Cl. CPC H10P 72/7612; H01J 37/32623; H01J 37/32834; H01J 37/32853; H10P 72/72; H01J 2237/3341

(57) ABSTRACT

Embodiments disclosed herein generally relate to processes for etching a bevel of a semiconductor substrate in a processing chamber. The process includes lifting a substrate away from an electrostatic chuck (ESC) using lift pins, and generating plasma via provision of a radio frequency (RF) bias to the ESC, where the plasma etches the substrate and includes a high density plasma formed below the substrate and having a first charge carrier density, and a low density plasma formed above the substrate and having a second charge carrier density lower than the first charge carrier density. Implementing such processes for etching the bevel results in various improvements in the manufacturing of semiconductor substrates.

### BACKGROUND

### Field

Embodiments of the present disclosure generally relate to processes for semiconductor device manufacturing, and, more specifically, relate to processes for etching a bevel of a semiconductor substrate in a processing chamber.

### Description of the Related Art

During deposition of materials (e.g., film layers) onto a semiconductor substrate, undesired films often form at an edge region of the substrate. To remove the undesired films, the substrate is typically moved from a deposition chamber to a bevel etch chamber. In the bevel etch chamber, a mask is placed over the substrate and the edge region undergoes etching to remove the undesired films.

However, moving the substrate from the deposition chamber to the bevel etch chamber and performing ex-situ bevel etching can complicate substrate manufacturing. For example, transferring the substrate from the deposition chamber to the bevel etch chamber increases the risk of substrate contamination due to exposure of the substrate to environment external to the deposition chamber. Ex-situ etching can also increase process non-uniformity between substrates or batches of substrates, and reduce overall device throughput.

Thus, there is a need for improved bevel etching techniques.

### SUMMARY

Embodiments of the present disclosure generally relate to processes for etching a bevel of a semiconductor substrate in a processing chamber.

One exemplary method for processing includes lifting a substrate away from an electrostatic chuck (ESC) using lift pins, and generating plasma via provision of a radio frequency (RF) bias to the ESC, wherein the plasma etches the substrate and includes a high density plasma formed below the substrate and having a first charge carrier density, and a low density plasma formed above the substrate and having a second charge carrier density lower than the first charge carrier density.

Another exemplary method for processing includes lifting a substrate away from an ESC using lift pins, introducing a clean gas to a processing chamber including the substrate and the ESC, and generating plasma via provision of a RF bias to the ESC, wherein the plasma etches the substrate and includes a high density plasma formed below the substrate and having a first charge carrier density, and a low density plasma formed above the substrate and having a second charge carrier density lower than the first charge carrier density.

Another exemplary method for processing includes depositing one or more film layers on a substrate disposed on an ESC, lifting the substrate away from the ESC using lift pins, and generating plasma via provision of a RF bias to the ESC, wherein the plasma etches the substrate and includes a high density plasma formed below the substrate and having a first charge carrier density, and a low density plasma formed above the substrate and having a second charge carrier density lower than the first charge carrier density.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 shows a schematic illustration of an apparatus that can be used to conduct processing methods, according to embodiments.

FIG. 2 is a flow diagram of a method of processing a substrate of FIG. 1, according to embodiments.

FIGS. 3A-3C show schematic cross-sectional views of the substrate of FIG. 1 at various stages of the method of FIG. 2, according to embodiments.

FIGS. 4A-4B show partial cross-sectional views of the substrate of FIG. 1 and FIGS. 3A-3C during different stages of the method described with reference to FIG. 2, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments disclosed herein generally relate to processing methods for use in semiconductor device manufacturing. More particularly, embodiments described herein relate to a method for etching a bevel of a substrate in a processing chamber also utilized to deposit one or more layers on the substrate. Etching the bevel of the substrate in the same processing chamber within which deposition is performed, or in-situ, simplifies manufacturing processes and reduces risk of substrate contamination relative to conventional etching techniques.

FIG. 1 shows a schematic illustration of a substrate processing system 132 that can be used to conduct processing methods in accordance with embodiments described herein. Examples of suitable systems, which can be used as the substrate processing system 132, include the CENTURA® systems which may use a DxZ™ processing chamber, PRECISION™ 5000 systems, PRODUCER® SE or GT processing chamber or system, which are commercially available from Applied Materials, Inc., Santa Clara, Calif. It is contemplated that other processing systems, including those available from other manufacturers, may be adapted to practice the embodiments described herein.

The substrate processing system 132 includes a processing chamber 100 coupled to a gas panel 130 and a controller 110.

The processing chamber 100 may be a plasma-enhanced chemical vapor deposition (PECVD) chamber as shown, or other suitable plasma processing chamber. Examples of a processing chamber 100 that may be adapted to benefit from the disclosure include PECVD chambers, such as but not limited to the CENTURA® apparatus, the PRODUCER® apparatus, the PRODUCER® GT apparatus, the PRODUCER® XP Precision™ apparatus, the PRODUCER® SE™ apparatus, and the TESSERACT® apparatus, which are available from Applied Materials, Inc., Santa Clara, Calif. It is contemplated that processing chambers from other manufacturers may also be adapted to benefit from the embodiments described herein.

Although FIG. 1 described herein is illustrative of a PECVD chamber, the processing chamber 100 should not be construed or interpreted as limiting the scope of the embodiments described herein. The embodiments described herein can be equally applied to an apparatus utilized for chemical vapor deposition (CVD), physical vapor deposition (PVD), implanting, annealing, and plasma-treating materials on semiconductor substrates, among others.

The processing chamber 100 generally includes a top 124, a side 101, and a bottom wall 122 that define an interior processing volume 126. An electrostatic chuck (ESC) 150 is provided in the interior processing volume 126 of the processing chamber 100. The ESC 150 is supported by a stem 160 and can be fabricated from aluminum, ceramic, and other suitable materials. The ESC 150 can be moved in a vertical direction inside the processing chamber 100 using a displacement mechanism (not shown).

The ESC 150 includes a first edge ring 180 disposed about the ESC 150, and a second edge ring 182 disposed about the ESC 150 and the first edge ring 180. The edge rings 180, 182 protect the ESC 150 and/or a substrate 190 disposed on a support surface 192 of the ESC 150. In some aspects, the edge rings 180, 182 are made of alumina (Al₂O₃) or other suitable material. In certain embodiments, one or more additional processing rings, can also be disposed about the ESC 150 and arranged along with the first edge ring 180 and/or second edge ring 182 to protect the ESC 150 and/or substrate 190.

A temperature sensor 172, such as a thermocouple, may be disposed in the processing chamber 100 to monitor temperature within the processing chamber 100 during processing of a substrate. In certain embodiments, the temperature sensor 172 is embedded in the side 101 of the processing chamber 100. In certain embodiments, the temperature sensor 172 is embedded in the ESC 150 to monitor the temperature of the ESC 150. The measured temperature can be used by the controller 110 to control a temperature of the processing chamber 100 or the ESC 150 during film deposition and/or etching of the substrate 190. As an example, the processing chamber 100 can be heated by a heater coupled to and/or embedded within one or more of the top 124, the side 101, the bottom wall 122, and/or the ESC 150. The heater can be regulated by the controller 110. In certain embodiments, the heater is a resistive heater and the ESC 150 is resistively heated by applying an electric current from a power supply 106.

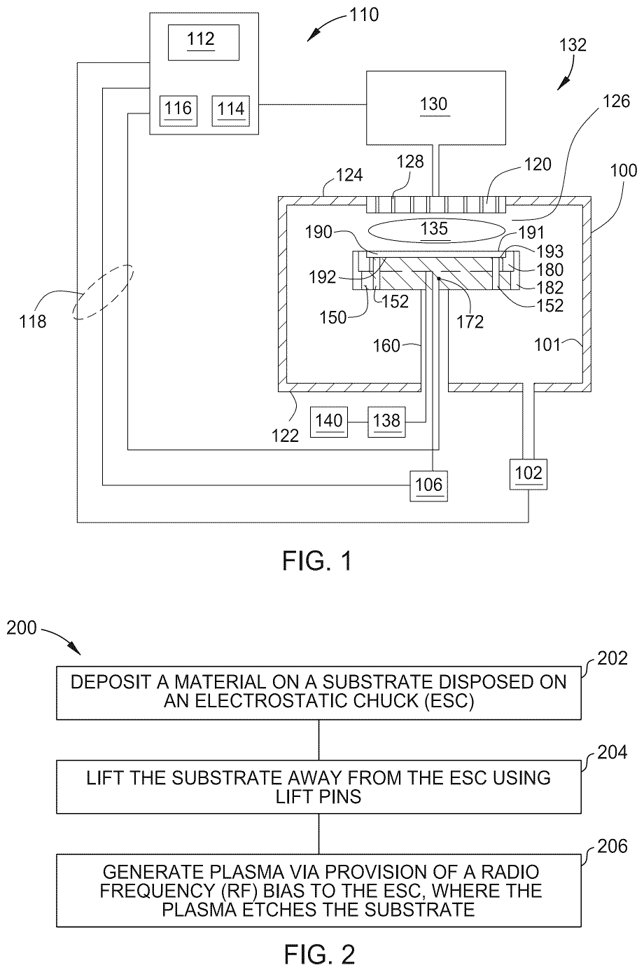

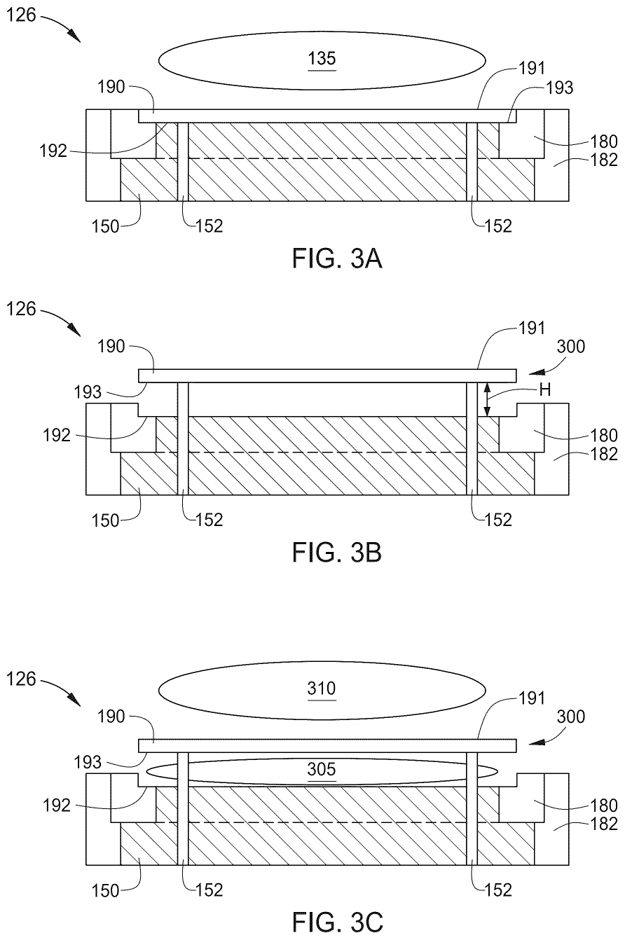

To facilitate transfer of the substrate 190 to and from the ESC 150, the ESC 150 includes a plurality of lift pins 152. The plurality of lift pins 152 are movably disposed in openings formed through the ESC 150. Generally, the lift pins 152 are configured to press against a bottom surface 193 of the substrate 190 to lift the substrate 190 upwards, off the support surface 192 of the ESC 150 and the first edge ring 180 and toward the top 124. Movement of the lift pins 152 and the substrate 190 is described in further detail with reference to FIG. 2 and FIGS. 3A-3C.

A vacuum pump 102 is coupled to a port formed in the bottom of the processing chamber 100. The vacuum pump 102 can be used to maintain a desired gas pressure in the processing chamber 100. The vacuum pump 102 also evacuates post-processing gases and by-products of the process from the processing chamber 100. Although not shown, the substrate processing system 132 may further include additional equipment for controlling the chamber pressure, for example, valves (e.g., throttle valves and isolation valves) positioned between the processing chamber 100 and the vacuum pump 102 to control the chamber pressure.

A showerhead 120 having a plurality of apertures 128 is disposed on the top of the processing chamber 100 above the ESC 150. The apertures 128 of the showerhead 120 are utilized to introduce deposition gas into the processing chamber 100. The apertures 128 may have different sizes, number, distributions, shape, design, and diameters to facilitate the flow of the various deposition gases for different process requirements. The showerhead 120 is connected to the gas panel 130 that allows the deposition gas to supply to the interior processing volume 126 during processing. A deposition plasma 135 is formed from the deposition gas exiting the showerhead 120 to enhance thermal decomposition of the deposition gas, resulting in the deposition of material on a top surface 191 of the substrate 190.

One or more radio frequency (RF) power sources 140 provide a bias potential (e.g., RF bias) through a matching network 138 to the ESC 150 to facilitate generation of the deposition plasma 135. As an example, the RF power sources 140 may provide between 100 watts (W) and 3,000 W at a frequency ranging between 2 megahertz (MHz) and 60 MHz. The RF power sources 140 and matching network 138 may also be coupled to the showerhead 120 and/or an antenna (not shown) disposed exterior to the processing chamber 100. As such, the showerhead 120 and the ESC 150 may form a pair of spaced apart electrodes in the interior processing volume 126.

The controller 110 includes a central processing unit (CPU) 112, a memory 116, and a support circuit 114 utilized to control the process sequence and regulate the gas flows from the gas panel 130. The CPU 112 can be of any form of a general purpose computer processor that can be used in an industrial setting. The software routines can be stored in the memory 116, such as random access memory, read only memory, floppy, or hard disk drive, or other form of digital storage. The support circuit 114 is conventionally coupled to the CPU 112 and may include cache, clock circuits, input/output systems, power supplies, and the like. Bi-directional communications between the controller 110 and the various components of the substrate processing system 132 are handled through numerous signal cables collectively referred to as signal buses 118, some of which are illustrated in FIG. 1.

Other deposition chambers may also benefit from the deposition processes described and discussed herein and the parameters listed above may vary according to the particular deposition chamber used to process the substrate 190. For example, other deposition chambers may have a larger or smaller volume, requiring gas flow rates that are larger or smaller than those recited for deposition chambers available from Applied Materials, Inc. In one or more embodiments, film can be deposited using a PRODUCER® SE or GT processing chamber or system which is commercially available from Applied Materials, Inc., Santa Clara, California.

Techniques for processing the substrate 190 are described with reference to FIG. 2 and FIGS. 3A-3C, and can be implemented by the controller 110 of FIG. 1. FIG. 2 is a flow diagram of a method 200 of processing the substrate 190 of FIG. 1, according to embodiments. FIGS. 3A-3C show schematic cross-sectional views of the substrate 190 of FIG. 1 at various stages of the method 200 of FIG. 2, according to embodiments. Accordingly, FIG. 2 and FIGS. 3A-3C are described together herein for clarity purposes.

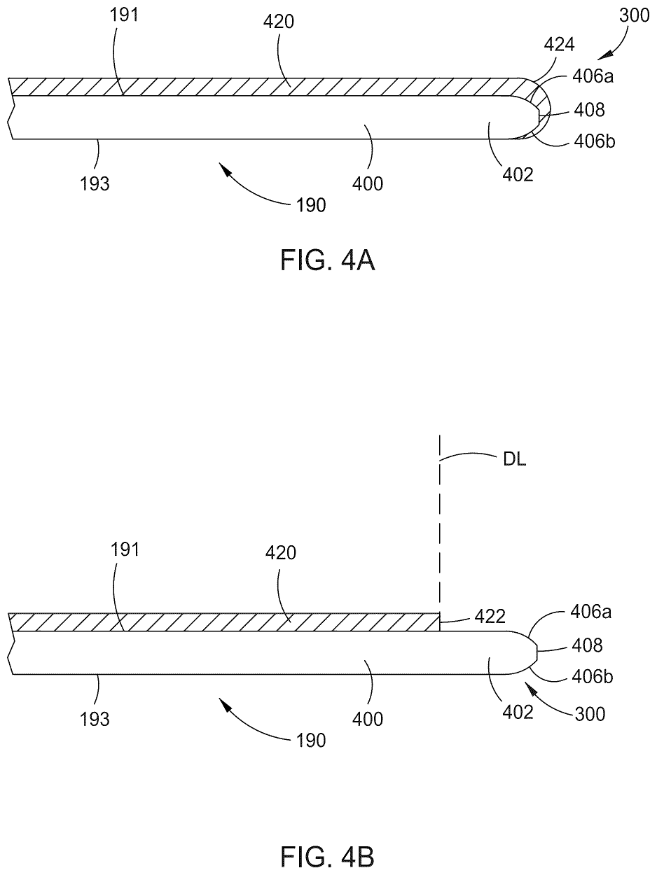

The method 200 begins at operation 202, where a material is deposited on the substrate 190 disposed on the ESC 150, as shown in FIG. 3A. The material is deposited on the top surface 191 of the substrate 190 via the deposition plasma 135, forming a film layer (e.g., film layer 420 shown in FIG. 4A). While the material is deposited on the substrate 190, the ESC 150 applies a chucking voltage to the substrate 190 to chuck the substrate 190 to the ESC 150.

In certain embodiments, the deposition of the material at operation 202 includes a PECVD process. For example, in such embodiments, the deposition of the material at operation 202 can be performed using a capacitively coupled PECVD (CC-PECVD) process, an inductively coupled PECVD (ICP-PECVD) process, a microwave PECVD (MW-PECVD) process, a remote plasma PECVD (RP-PECVD) process, or the like.

In general, the following exemplary deposition process parameters can be used to form the film layer.

In certain embodiments, operation 202 is performed while the substrate 190 is heated to a substrate temperature ranging between 100 Celsius (° C.) and 700° C. (e.g., between 200° C. and 500° C.). In certain embodiments, operation 202 is performed while the chamber pressure is adjusted to and/or maintained at a chamber pressure of about 1 Torr to about 20 Torr (e.g., between about 2 Torr and about 10 Torr).

In one or more examples, the deposition plasma 135 is formed in the interior processing volume 126 from a deposition gas. The deposition gas can be introduced into the interior processing volume 126 via the showerhead 120 shown in FIG. 1.

The deposition gas may contain one or more silicon precursors, one or more nitrogen precursors, one or more phosphorus precursors, and/or one or more carrier gases. The silicon precursor, the nitrogen precursor, the phosphorus precursor, and/or the carrier gas can be co-flowed together through the showerhead 120 when exposing the substrate 190 to the deposition gas. The flow rate of the silicon precursor can be in a range from about 200 standard cubic centimeter per minute (sccm) to about 5,000 sccm (e.g., from about 400 sccm to about 2,000 sccm). The flow rate of the nitrogen precursor can be in a range from about 200 sccm to about 5,000 sccm (e.g., from about 400 sccm to about 2,000 sccm). The flow rate of the phosphorus precursor can be in a range from about 10 sccm to about 1,000 sccm (e.g., from about 50 sccm to about 500 sccm). The flow rate of the carrier gas can be in a range from about 500 sccm to about 20,000 sccm (e.g., from about 2,000 sccm to about 10,000 sccm).

The phosphorus precursor can be or include phosphine (PH₃), methylphosphine (CH₃PH₂), ethylphosphine (CH₃CH₂PH₂), propylphosphine (CH₃(CH₂)₂PH₂), butylphosphine (CH₃(CH₂)₃PH₂), phosphorus oxychloride (POCl₃), trimethylphosphate ((CH₃)₃P), triethylphosphate ((CH₃(CH₂))₃P), isomers thereof, or any combination thereof. The silicon precursor can be or include silane (SiH₄), disilane (Si₂H₆), trisilane (Si₃H₈), tetrasilane (Si₄H₁₀), pentasilane (Si₅H₁₂), methylsilane (CH₃SiH₃), chlorosilane (SiH₃Cl), dichlorosilane (SiH₂Cl₂), trichlorosilane (SiHCl₃), silicon tetrachloride (SiCl₄), hexachlorodisilane (Si₂Cl₆), or any combinations thereof. The nitrogen precursor can be or include ammonia (NH₃), hydrazine (N₂H₄), dimethyl hydrazine ((CH₃)₂N₂H₂), tertert-butylhydrazine (C₄H₉N₂H₃), phenylhydrazine (C₆H₅N₂H₃), 2,2′-azoisobutane ((CH₃)₆C₂N₂), ethylazide (C₂H₅N₃), isomers thereof, or any combinations thereof. The carrier gas contains nitrogen (N₂), argon, helium, plasma thereof, or any combination thereof. In one or more examples, the deposition gas contains phosphine, silane, ammonia, and one or more carrier gases.

In certain embodiments, after the film layer is formed on the substrate 190, the deposition gas is purged from the interior processing volume 126. The substrate 190 may also be de-chucked from the ESC 150 simultaneously with the purge of the deposition gas, or after the purge of the deposition gas. In certain embodiments, multiple film layers are formed on the substrate 190 and/or the operation 202 is repeated to complete a deposition recipe.

At operation 204, the lift pins 152 lift the substrate 190 away from the support surface 192 of the ESC 150 and toward the top 124, as shown in FIG. 3B. The lift pins 152 position the substrate 190 at a height (H), which is formed between the bottom surface 193 of the substrate 190 and the support surface 192 of the ESC 150. Lifting the substrate 190 off the ESC 150 to the height (H) exposes an edge region 300 of the substrate 190.

The height (H) to which the substrate 190 is lifted can be determined based on a target, or desired etch profile for the edge region 300. For example, the height (H) can be between 2 millimeters (mm) and 30 mm (e.g., between 4 mm and 28 mm, 6 mm and 26 mm, 8 mm and 24 mm, or 10 mm and 22 mm). The height (H) may also be adjusted during performance of operation 206 below, such that the substrate 190 is moved up and/or down during the processing at operation 206 to achieve a target etch profile.

After the substrate 190 is lifted from the support surface 192, a clean gas is introduced into the interior processing volume 126. The clean gas can include argon (Ar), an oxygen gas (O₂), a nitrogen gas (N₂), or any other suitable clean gas. The clean gas can be introduced into the interior processing volume 126 via the showerhead 120 shown in FIG. 1.

At operation 206, plasma, which is comprised of a high density clean plasma 305 and a low density clean plasma 310 (collectively referred to herein as “plasma 305, 310”), is generated via provision of an RF bias (e.g., bottom feed RF bias) to the ESC 150, as shown in FIG. 3C. The high density clean plasma 305 includes a plasma with a very large number of charged particles (e.g., charge carriers) packed closely together in a given volume (e.g., a high concentration/density of ions and electrons within the plasma). Comparatively, the low density clean plasma 310 includes a plasma with a lower number of charged particles in a given volume compared to the high density clean plasma 305 (e.g., a low concentration/density of ions and electrons within the plasma).

As an example, the high density clean plasma 305 can have a charge carrier density, such as an electron density, ranging between 10¹¹ cm⁻³ and 10¹³ cm⁻³, while the low density clean plasma 310 can have a charge carrier density, such as an electron density, ranging between 10⁸ cm⁻³ and 10¹⁰ cm⁻³. In other words, the charge carrier density of the high density clean plasma 305 is greater than the charge carrier density of the low density clean plasma 310.

The high density clean plasma 305 is primarily disposed between the bottom surface 193 of the substrate 190 and the support surface 192 of the ESC 150 (i.e., below the substrate 190), but also reaches (or contacts) a portion of the edge region 300. The low density clean plasma 310 is primarily disposed above (or over) the top surface 191 of the substrate 190, but also reaches (or contacts) a portion of the edge region 300.

To adjust the charge carrier density of the high density clean plasma 305 and/or the low density clean plasma 310, the height (H) to which the substrate 190 is lifted can be adjusted. Generally, a lower height (H) corresponds to a higher charge carrier density for the high density clean plasma 305 and a lower charge carrier density for the low density clean plasma 310. In other words, decreasing the height (H) will increase the charge carrier density for the high density clean plasma 305 and will decrease the charge carrier density for the low density clean plasma 310, while increasing the height (H) will decrease the charge carrier density for the high density clean plasma 305 and will increase the charge carrier density for the low density clean plasma 310.

The plasma 305, 310 etches portions of the edge region 300 and removes portions of the film layer formed at the edge region 300 due to a chemical reaction between the plasma 305, 310, the substrate 190, and the film layer. An example of an etched edge region 300 is described in further detail with reference to FIG. 4B.

The high density clean plasma 305 exhibits a first etch rate, while the low density clean plasma 310 exhibits a second etch rate. As a result of the higher charge carrier density of the high density clean plasma 305, the first etch rate is greater than the second etch rate. Thus, the high density clean plasma 305 can etch the substrate 190, and/or any film layers formed thereon, at a higher (e.g., faster) rate than the low density clean plasma 310.

To modify the etch rate of the high density plasma 305 and/or the low density clean plasma 310, the height (H) of the substrate 190 can be adjusted. Decreasing the height (H) will increase the etch rate for the high density clean plasma 305 and will decrease the etch rate for the low density clean plasma 310, while increasing the height (H) will decrease the etch rate for the high density clean plasma 305 and will increase the etch rate for the low density clean plasma 310. Accordingly, a target etch profile for the substrate 190 can be achieved based upon the height (H) of the substrate 190 during processing.

Generally, the substrate 190 acts as a barrier between the volume of the interior processing volume 126 between the substrate 190 and the ESC 150 and the volume of the interior processing volume 126 above the substrate 190. This barrier causes the formation of the high density clean plasma 305 below the substrate 190 and the low density clean plasma 310 above the substrate 190.

Although the plasma 305, 310 is shown as separately including the high density clean plasma 305 and the low density clean plasma 310, the plasma 305, 310 can include a singular plasma with a density gradient that transitions between the high density clean plasma 305 and the low density clean plasma 310. In other words, the high density clean plasma 305 and the low density clean plasma 310 can be portions of the same plasma.

To form and/or maintain the plasma 305, 310, the RF bias can be applied at a power level of, for example, no more than 200 W to avoid potential arcing damage. As an example, the processing chamber 100 can be maintained at a pressure between 100 and 500 millitorr (mTorr) (e.g., between 150 and 450 mTorr, 200 and 400 mTorr, or 250 and 450 mTorr). The pressure is maintained between 100 and 500 mTorr to increase ion concentration, which results in faster etching relative to lower pressures.

Once a target amount of material has been etched from the edge region 300 of the substrate 190 by the plasma 305, 310, the application of RF bias to the ESC 150 and the introduction of the clean gas are halted. The clean gas can then be purged from the interior processing volume 126, and the substrate 190 can be transferred.

Etching the substrate 190 in the same chamber (e.g., processing chamber 100) in which film layers are deposited on the substrate 190, i.e., in-situ, simplifies fabrication of the substrate 190 by eliminating use of a separate bevel etch chamber. In-situ etching of the substrate 190 in the processing chamber 100 can also reduce manufacturing costs (e.g., relative to conventional etching techniques) by reducing an amount of chambers used to fabricate the substrate 190. The reduction in chambers thereby results in lower chamber-associated maintenance costs.

Further, in-situ etching reduces risk of contaminating the substrate 190 because the substrate 190 can be etched without transferring the substrate 190 from the processing chamber 100 to a separate bevel etch chamber. In other words, the substrate 190 is etched without being exposed to an environment external to the processing chamber 100. Additionally, in-situ etching provides stable chamber conditions for process uniformity/consistency between substrates and/or batches, and eliminates variations from chamber to chamber differences. Throughput is also increased due to reduced wafer transfer time and/or down time.

FIGS. 4A-4B show partial cross-sectional views of the substrate 190 of FIG. 1 and FIGS. 3A-3C during the different stages of the method described with reference to FIG. 2, according to embodiments.

FIG. 4A depicts the substrate 190 after operation 202 (and during operation 204), where the film layer 420 has been formed by the material deposited on the substrate 190. A thickness of the film layer 420 is substantially uniform along an inner region 400 of the substrate 190, but tapers around the edge region 300 of the substrate 190. That is, an outer region 424 of the film layer 420 extends over, and decreases in thickness around an upper bevel 406a, a lower bevel 406b, and an apex 408 formed at the edge region 300 of the substrate 190. The upper bevel 406a extends from the top surface 191 to the apex 408, and the lower bevel 406b extends from the bottom surface 193 to the apex 408.

FIG. 4B depicts the substrate 190 after operation 206, where the edge region 300 and the film layer 420 have been etched by the plasma 305, 310. After the edge region 300 has been etched, the outer region 424 of the film layer 420 is removed from the outer region 402 of the substrate 190. A vertical dividing line (DL) extends along an outer edge 422 of the film layer 420 and is used to describe a point on the top surface 191 of the substrate 190 to which the outer region 424 of the film layer 420 is removed. In other words, the outer region 424 of the film layer 420 is etched back from the edge region 300 to the dividing line (DL). The remaining portion of the film layer 420 is not affected by the plasma 305, 310, which eliminates particle issues associated with low quality film layers at the outer edge 422 (e.g., experienced with conventional etching techniques). The remaining portion of the film layer 420 is not affected, or is only imperceptibly affected, because the film layer 420 is primarily contacted by the low density clean plasma 310, which does not etch, or does not substantively etch, the film layer 420.

A position of the dividing line (DL) relative to the top surface 191 can be adjusted based on the height (H) of the lift pins 152 during etching of the substrate 190. For example, the dividing line (DL) can be moved closer to the inner region 400 of the substrate 190 at a lift pin height (H) of 5 mm, and closer to the outer region 402 of the substrate at a lift pin height (H) of 20 mm.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

While various examples of the invention have been described above, it should be understood that they have been presented by way of example only, and not by way of limitation. Likewise, the various diagrams may depict an example architectural or other configuration for the disclosure, which is done to aid in understanding the features and functionality that can be included in the disclosure. The disclosure is not restricted to the illustrated example architectures or configurations, but can be implemented using a variety of alternative architectures and configurations. Additionally, although the disclosure is described above in terms of various example examples and aspects, it should be understood that the various features and functionality described in one or more of the individual examples are not limited in their applicability to the particular example with which they are described. They instead can be applied, alone or in some combination, to one or more of the other examples of the disclosure, whether or not such examples are described, and whether or not such features are presented as being a part of a described example. Thus the breadth and scope of the present disclosure should not be limited by any of the above-described example examples.

All references cited herein are incorporated herein by reference in their entirety. To the extent publications and patents or patent applications incorporated by reference contradict the disclosure contained in the specification, the specification is intended to supersede and/or take precedence over any such contradictory material.

Unless otherwise defined, all terms (including technical and scientific terms) are to be given their ordinary and customary meaning to a person of ordinary skill in the art, and are not to be limited to a special or customized meaning unless expressly

### So Defined Herein.

Terms and phrases used in this application, and variations thereof, especially in the appended claims, unless otherwise expressly stated, should be construed as open ended as opposed to limiting. As examples of the foregoing, the term ‘including’ should be read to mean ‘including, without limitation,’ ‘including but not limited to,’ or the like; the term ‘including’ as used herein is synonymous with ‘including,’ ‘containing,’ or ‘characterized by,’ and is inclusive or open-ended and does not exclude additional, unrecited elements or method steps; the term ‘having’ should be interpreted as ‘having at least;’ the term ‘includes’ should be interpreted as ‘includes but is not limited to;’ the term ‘example’ is used to provide example instances of the item in discussion, not an exhaustive or limiting list thereof; adjectives such as ‘known’, ‘normal’, ‘standard’, and terms of similar meaning should not be construed as limiting the item described to a given time period or to an item available as of a given time, but instead should be read to encompass known, normal, or standard technologies that may be available or known now or at any time in the future; and use of terms like ‘preferably,’ ‘preferred,’ ‘desired,’ or ‘desirable,’ and words of similar meaning should not be understood as implying that certain features are critical, essential, or even important to the structure or function of the invention, but instead as merely intended to highlight alternative or additional features that may or may not be utilized in a particular example of the invention. Likewise, a group of items linked with the conjunction ‘and’ should not be read as requiring that each and every one of those items be present in the grouping, but rather should be read as ‘and/or’ unless expressly stated otherwise. Similarly, a group of items linked with the conjunction ‘or’ should not be read as requiring mutual exclusivity among that group, but rather should be read as ‘and/or’ unless expressly stated otherwise.

The term “including as used herein is synonymous with “including,” “containing,” or “characterized by” and is inclusive or open-ended and does not exclude additional, unrecited elements or method steps.

All numbers expressing quantities of ingredients, reaction conditions, and so forth used in the specification are to be understood as being modified in all instances by the term ‘about.’ Accordingly, unless indicated to the contrary, the numerical parameters set forth herein are approximations that may vary depending upon the desired properties sought to be obtained. At the very least, and not as an attempt to limit the application of the doctrine of equivalents to the scope of any claims in any application claiming priority to the present application, each numerical parameter should be construed in light of the number of significant digits and ordinary rounding approaches.

Furthermore, although the foregoing has been described in some detail by way of illustrations and examples for purposes of clarity and understanding, it is apparent to those skilled in the art that certain changes and modifications may be practiced. Therefore, the description and examples should not be construed as limiting the scope of the invention to the specific examples and examples described herein, but rather to also cover all modification and alternatives coming with the true scope and spirit of the invention.

What is claimed is:

1. A processing method, comprising:
lifting a substrate away from an electrostatic chuck (ESC) using lift pins; and
generating plasma via provision of a radio frequency (RF) bias to the ESC, wherein the plasma etches the substrate and comprises:
a high density plasma formed below the substrate and having a first charge carrier density; and
a low density plasma formed above the substrate and having a second charge carrier density lower than the first charge carrier density.

2. The processing method of claim 1, wherein the lift pins lift the substrate to a height (H), and wherein the height (H) is formed between a bottom surface of the substrate and a support surface of the ESC.

3. The processing method of claim 2, wherein the height (H) is between 2 millimeters (mm) and 30 mm.

4. The processing method of claim 2, wherein the height (H) is determined based on a target etch profile for the substrate.

5. The processing method of claim 2, wherein the height (H) is determined based on at least one of a target charge carrier density of the high density plasma or a target charge carrier density of the low density plasma.

6. The processing method of claim 2, wherein the height (H) is adjusted while the plasma etches the substrate.

7. The processing method of claim 6, wherein the height (H) is adjusted to modify at least one of a target charge carrier density of the high density plasma or a target charge carrier density of the low density plasma.

8. The processing method of claim 1, wherein lifting the substrate away from the ESC exposes an edge region of the substrate.

9. The processing method of claim 1, wherein the high density plasma contacts a bottom surface of the substrate, an edge region of the substrate, and a portion of a top surface of the substrate.

10. The processing method of claim 1, wherein the high density plasma removes portions of a film layer formed at an edge region of the substrate.

11. The processing method of claim 1, wherein the RF bias is applied at a power level of no more than 200 watts (W).

12. A processing method, comprising:
lifting a substrate away from an electrostatic chuck (ESC) using lift pins;
introducing a clean gas to a processing chamber including the substrate and the ESC; and
generating plasma via provision of a radio frequency (RF) bias to the ESC, wherein the plasma etches the substrate and comprises:
a high density plasma formed below the substrate and having a first charge carrier density; and
a low density plasma formed above the substrate and having a second charge carrier density lower than the first charge carrier density.

13. The processing method of claim 12, wherein the clean gas is at least one of argon (Ar), an oxygen gas (O₂), and a nitrogen gas (N₂).

14. The processing method of claim 12, wherein a pressure of the processing chamber is maintained between 100 millitorr (mTorr) and 500 mTorr.

15. The processing method of claim 12, further comprising:
purging the clean gas from the processing chamber; and
removing the substrate from the processing chamber.

16. A processing method, comprising:
depositing one or more film layers on a substrate disposed on an electrostatic chuck (ESC);
lifting the substrate away from the ESC using lift pins; and
generating plasma via provision of a radio frequency (RF) bias to the ESC, wherein the plasma etches the substrate and comprises:
a high density plasma formed below the substrate and having a first charge carrier density; and
a low density plasma formed above the substrate and having a second charge carrier density lower than the first charge carrier density.

17. The processing method of claim 16, wherein depositing the one or more film layers, lifting the substrate away from the ESC, and generating the plasma that etches the substrate are performed in one processing chamber.

18. The processing method of claim 16, further comprising:
purging deposition gas used to form the one or more film layers before lifting the substrate away from the ESC.

19. The processing method of claim 16, further comprising:
de-chucking the substrate from the ESC before lifting the substrate away from the ESC.

20. The processing method of claim 16, wherein the substrate is chucked to the ESC during the depositing of the one or more film layers.
